(19) United States
(12) Patent Application Publication
(10) Pub. No.: US 2024/0413796 A1
(43) Pub. Date: Dec. 12, 2024

(54) LOW NOISE AMPLIFIER CIRCUIT AND RF FRONT-END MODULE

(71) Applicant: RADROCK (SHENZHEN) TECHNOLOGY CO., LTD., Shenzhen (CN)

(72) Inventors: Meiyu LI, Shenzhen (CN); Nan SONG, Shenzhen (CN); Jianxing NI, Shenzhen (CN)

(73) Assignee: RADROCK (SHENZHEN) TECHNOLOGY CO., LTD., Shenzhen (CN)

(21) Appl. No.: 18/812,182

(22) Filed: Aug. 22, 2024

Related U.S. Application Data
(63) Continuation of application No. PCT/CN2023/075838, filed on Feb. 14, 2023.

(30) Foreign Application Priority Data
Feb. 22, 2022 (CN) 202210165391.7

(51) Int. Cl. H03F 1/26; H03F 3/195; H03F 3/68; H03F 3/72

(52) U.S. Cl. CPC H03F 1/26; H03F 3/195; H03F 3/68; H03F 3/72; H03F 2200/294; H03F 2200/451; H03F 2203/7215; H03F 2203/7221

(57) ABSTRACT

Disclosed are a low noise amplifier circuit and an RF front-end module. The low noise amplifier circuit includes a signal input end, a signal output end, a first amplifier circuit, a second amplifier circuit and a first switching circuit; the first amplifier circuit and second amplifier circuit are connected in series between an signal input end and an signal output end; an end of the first switching circuit is connected with an output end of the first amplifier circuit, and another end is connected with the signal output end. It is configured that the first switching circuit is turned on when the low noise amplifier circuit works in the high linearity mode, and the first switching circuit is turned off when the low noise amplifier circuit works in the high gain mode. The application can effectively enhance the gain and linearity of the low noise amplifier circuit.

### CROSS-REFERENCE TO RELATED APPLICATIONS

This application is a continuation of International Application No. PCT/CN2023/075838, filed on Feb. 14, 2023, which claims priority to Chinese Patent Application No. 202210165391.7, filed on Feb. 22, 2022. All of the aforementioned applications are incorporated herein by reference in their entireties.

### TECHNICAL FIELD

The application relates to the technical field of radio frequency (RF) integrated circuits, in particular to a low noise amplifier circuit and an RF front-end module.

### BACKGROUND

Low Noise Amplifier (LNA) is commonly employed as the front-end amplifier of high-frequency or intermediate-frequency signals in various radio receivers, as well as the signal amplifier in high-sensitivity electronic detection equipment. Low noise amplifier is the main part of RF front-end module. Aside from noise coefficient, linearity, impedance matching, and power consumption, the gain of a low noise amplifier is an important metric for measuring performance. To reduce the influence of noise on a low noise amplifier circuit, the low noise amplifier must provide sufficient gain and linearity while maintaining broadband impedance matching. Therefore, when designing low noise amplifiers, it is critical to develop strong metrics for gain and linearity in order to increase the sensitivity and communication quality of the RF front-end modules.

### SUMMARY

The embodiments of the application provide a low noise amplifier circuit and an RF front-end module, aiming at addressing the problem of low linearity of the existing low noise amplifiers.

A low noise amplifier circuit is provided, including a signal input end, a signal output end, a first amplifier circuit, a second amplifier circuit, a first switching circuit and an induction regulating circuit. An input end of the first amplifier circuit is coupled to the signal input end, an output end of the first amplifier circuit is coupled to an input end of the second amplifier circuit, and an output end of the second amplifier circuit is coupled to the signal output end; an end of the first switching circuit is connected with the output end of the first amplifier circuit, and another end of the first switching circuit is connected with the signal output end; an end of the induction regulating circuit is connected with the first amplifier circuit, and another end of the induction regulating circuit is connected with a ground terminal; and the low noise amplifier circuit includes a high gain mode and a high linearity mode, wherein in the high gain mode, the first switching circuit is turned on, and the induction regulating circuit presents a first inductance value; in the high linearity mode, the first switching circuit is turned off, and the induction regulating circuit presents a second inductance value, and the first inductance value is smaller than the second inductance value.

Further, the low noise amplifier circuit further includes a second switching circuit, an end of the second switching circuit is connected with the output end of the first amplifier circuit, and another end of the second switching circuit is connected with the input end of the second amplifier circuit; when the low noise amplifier circuit works in the high linearity mode, the second switching circuit is turned off, and when the low noise amplifier circuit works in the high gain mode, the second switching circuit is turned on.

Further, the induction regulating circuit includes a first regulating circuit and a second regulating circuit connected in parallel; the first regulating circuit includes a first regulating switch and a first regulating inductor connected in series, and the second regulating circuit includes a second regulating switch and a second regulating inductor; when the low noise amplifier circuit works in the high linearity mode, the first regulating switch is on and the second regulating switch is off; when the low noise amplifier circuit works in the high gain mode, the second regulating switch is on and the first regulating switch is off; wherein the inductance value of the first regulating inductor is greater than that of the second regulating inductor.

Further, the induction regulating circuit includes a plurality of regulating inductors and a gain switch; the plurality of regulating inductors are connected in series between the first amplifier circuit and the ground terminal, the gain switch is connected in parallel with any one of the regulating inductors, and when the low noise amplifier circuit works in the high linearity mode, the gain switch is off; when the low noise amplifier circuit works in the high gain mode, the gain switch is on.

Further, the induction regulating circuit includes an adjustable inductor; when the low noise amplifier circuit works in the high linearity mode, the inductance value of the adjustable inductor is adjusted to the second inductance value, and when the low noise amplifier circuit works in the high gain mode, the inductance value of the adjustable inductor is adjusted to the first inductance value.

Further, the first amplifier circuit includes a first amplifier transistor, a first end of the first amplifier transistor is coupled to the signal input end, a second end of the first amplifier transistor is connected to the induction regulating circuit, and a third end of the first amplifier transistor is coupled to the input end of the second amplifier circuit.

Further, the second amplifier circuit includes a second amplifier transistor, a first end of the second amplifier transistor is connected with a first power supply terminal, a second end of the second amplifier transistor is coupled to the third end of the first amplifier transistor, and a third end of the second amplifier transistor is coupled to the signal output end.

Further, the first amplifier transistor is a first MOS transistor (Metal-Oxide-Semiconductor Field-Effect Transistor, MOSFET), a gate of the first MOS transistor is the first end of the first amplifier transistor, a drain of the first MOS transistor is the second end of the first amplifier transistor, and a source of the first MOS transistor is the third end of the first amplifier transistor; the second amplifier transistor is a second MOS transistor, a gate of the second MOS transistor is the first end of the second amplifier transistor, a drain of the second MOS transistor is the second end of the second amplifier transistor, and a source of the second MOS transistor is the third end of the second amplifier transistor.

A low noise amplifier circuit is further provided, including a signal input end, a signal output end, a first amplifier circuit, a second amplifier circuit, a SPDT switching circuit and an induction regulating circuit. A first end of the SPDT switching circuit is connected with an output end of the first amplifier circuit, a second end of the SPDT switching circuit is connected with an input end of the second amplifier circuit, and a third end of the SPDT switching circuit is connected with the signal output end; an end of the induction regulating circuit is connected with the first amplifier circuit, and another end of the induction regulating circuit is connected with a ground terminal; and the low noise amplifier circuit includes a high gain mode and a high linearity mode; in the high gain mode, the SPDT switching circuit conducts the first end and the second end, and the induction regulating circuit presents a first inductance value; in the high linearity mode, the SPDT switching circuit conducts the first end and the third end, and the induction regulating circuit presents a second inductance value, and the first inductance value is smaller than the second inductance value.

Further, the SPDT switching circuit includes a moving end, a first fixed end and a second fixed end; the moving end of the SPDT switching circuit is connected with the output end of the first amplifier circuit, the first fixed end of the SPDT switching circuit is connected with the input end of the second amplifier circuit, and the second fixed end of the SPDT switching circuit is connected with the signal output end.

Further, the first amplifier circuit includes a first amplifier transistor, the first amplifier transistor is a MOS transistor, and a gate of the first amplifier transistor is coupled to the signal input end, a drain of the first amplifier transistor is connected with the induction regulating circuit, and a source of the first amplifier transistor is connected with the first end of the SPDT switching circuit.

Further, the second amplifier circuit includes a second amplifier transistor, the second amplifier transistor is a MOS transistor, a gate of the second amplifier transistor is connected to a first power supply terminal, a drain of the second amplifier transistor is connected to the second end of the SPDT switching circuit, and a source of the second amplifier transistor is coupled to the signal output end.

An RF front-end module is also provided, including the low noise amplifier circuit described above.

According to the low noise amplifier circuit and RF front-end module provided by the present application, an end of the first switching circuit is connected with the output end of the first amplifier circuit, and another end is connected with the signal output end. It is configured that when the low noise amplifier circuit works in the high gain mode, the first switching circuit is turned off, allowing the first amplifier circuit and second amplifier circuit to cooperate with each other to amplify the RF input signal, thus realizing the high gain of the low noise amplifier circuit. When the low noise amplifier circuit works in the high linearity mode, the first switching circuit is turned on to connect the output end of the first amplifier circuit with the signal output end, allowing the RF input signal to be amplified through the first amplifier circuit and then output from the signal output end, thus realizing the low gain of the low noise amplifier circuit. By controlling the on/off state of the first switch, the low noise amplifier circuit can achieve optimal performance in the high linearity mode, and then the noise coefficient, linearity and other parameters can also be optimized in the high linearity mode.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. For those of ordinary skill in this field, other drawings may be obtained according to these drawings without any creative effort.

FIG. 1 is a schematic circuit diagram of a low noise amplifier circuit according to an embodiment of the present application.

FIG. 2 is another schematic circuit diagram of a low noise amplifier circuit according to an embodiment of the present application.

FIG. 3 is another schematic circuit diagram of a low noise amplifier circuit according to an embodiment of the present application.

FIG. 4 is another schematic circuit diagram of a low noise amplifier circuit according to an embodiment of the present application.

FIG. 5 is another schematic circuit diagram of a low noise amplifier circuit according to an embodiment of the present application.

FIG. 6 is another schematic circuit diagram of a low noise amplifier circuit according to an embodiment of the present application.

Reference signs in the figures are as follows: 10. First amplifier circuit; 20. Second amplifier circuit; 30. First switching circuit; 40. Second switching circuit; 50. Induction regulating circuit; 51. First regulating circuit; 52. Second regulating circuit; 60. Single-Pole Double-Throw (SPDT) switching circuit.

### DETAILED DESCRIPTION OF THE EMBODIMENTS

The technical solutions in the embodiments of the present application will be clearly and completely described below with reference to the drawings in the embodiments of this application. Obviously, the described embodiments are merely part of the embodiments of this application, not all of them. Based on the embodiments in this application, all other embodiments obtained by those of ordinary skill in the art without creative effort belong to the protection scope of this application.

It should be understood that the exemplary embodiments may be embodied in many different forms and should not be construed as being limited to the exemplary embodiments set forth herein. Rather, these embodiments are provided so that this disclosure will be thorough and complete, and will fully convey the protection scope of this application to those skilled in the art. In the drawings, like reference signs refer to like elements throughout, and the size and relative sizes of layers and regions may be exaggerated for clarity.

It should be understood that when an element or layer is referred to as being “on”, “adjacent to”, “connected with” or “coupled to” other elements or layers, it may be directly on, adjacent to, connected with or coupled to other elements or layers, or intervening elements or layers. Rather, when an element is referred to as being “directly on”, “directly adjacent to”, “directly connected with” or “directly coupled to” other elements or layers, there is no intervening element or layer. It should be understood that although the terms first, second, third, etc. are used to describe various elements, components, areas, layers and/or parts, these elements, components, areas, layers and/or parts should not be limited by these terms. These terms are only used to distinguish one element, part, area, layer or part from another element, part, area, layer or part. Therefore, without departing from the teachings of this application, the first element, part, area, layer or part discussed below may be represented as the second element, part, area, layer or part.

Spatial terms such as “below”, “under”, “down”, “connected”, “above”, “on” and “up” may be used here for convenience of description to describe the relationship between one element or feature and other elements or features shown in the figures. It should be understood that in addition to the orientations shown in the figures, the spatial relationship terms are intended to include different orientations of devices in use and operation. For example, if the device in the figures is turned upside down, then the elements or features described as “below” or “under” other elements or features would be “above” or “on” other elements or features. Therefore, the exemplary terms “below” or “under” may include the orientations of “above” or “on”. The device may be otherwise oriented (rotated by 90 degrees or other orientations) and the spatial description terms used here are interpreted accordingly.

The terms used here are only for the purpose of describing specific embodiments and not as a limitation of the present application. As used herein, singular forms of “a”, “an” and “the/said” are also intended to include plural forms, unless the context clearly indicates otherwise. It should also be understood that the terms “comprise” and/or “include” used in this specification specify the presence of said features, integers, steps, operations, elements and/or components, but do not exclude the presence or addition of one or more other features, integers, steps, operations, elements, components and/or groups. As used herein, the term “and/or” includes any and all combinations of related listed items.

For a thorough understanding of this application, detailed structures and steps will be set forth in the following description, so as to illustrate the technical solution proposed in the present application. The preferred embodiments of the present application are described in detail as follows, but besides these detailed descriptions, the present application may also have other embodiments.

In a practical application process, low noise amplifiers are usually designed with multiple gain levels to meet the amplification requirements of received signals with different intensities. The low noise amplifier receives signal from the antenna, but the received signal strength is relatively weak, so it is necessary to adjust the gain level according to the signal strength. Particularly in the low gain mode, if the linearity of the low noise amplifier is inadequate and other paths interfere with the received signal, the noise will be seriously deteriorated, and the sensitivity of the receiver will be significantly diminished, which will have an impact on the communication quality in the future.

In view of this, this embodiment provides a low noise amplifier circuit, as shown in FIG. 1, which includes a signal input end Vin, a signal output end Vout, a first amplifier circuit 10, a second amplifier circuit 20, a first switching circuit 30 and an induction regulating circuit 50. An input end of the first amplifier circuit 10 is coupled to the signal input end Vin, an output end of the first amplifier circuit 10 is coupled to an input end of the second amplifier circuit 20, and an output end of the second amplifier circuit 20 is coupled to the signal output end Vout. An end of the first switching circuit 30 is connected with the output end of the first amplifier circuit 10, and another end of the first switching circuit 30 is connected with the signal output end Vout. An end of the induction regulating circuit 50 is connected with the first amplifier circuit 10, and another end of the induction regulating circuit 50 is connected with a ground terminal. The low noise amplifier circuit includes a high gain mode and a high linearity mode, in the high gain mode, the first switching circuit 30 is turned on, and the induction regulating circuit 50 presents a first inductance value; in the high linearity mode, the first switching circuit 30 is turned off, and the induction regulating circuit 50 presents a second inductance value, and the first inductance value is smaller than the second inductance value.

Here, the signal input end Vin is a port for receiving RF input signals. The signal output end Vout is a port for outputting amplified RF signals. The RF input signal is the RF signal to be amplified. The RF signal is a modulated electromagnetic wave signal. The amplified RF signal is obtained after the RF input signal is amplified by the first amplifier circuit 10 and the second amplifier circuit 20. The high linearity mode is the working state when the low noise amplifier circuit has high linearity. The gain of low noise amplifier circuit in the high linearity mode is usually low. The high gain mode is the working state when the low noise amplifier circuit has high gain.

Specifically, the input end of the first amplifier circuit 10 is coupled to the signal input end Vin, the output end of the first amplifier circuit 10 is coupled to the input end of the second amplifier circuit 20, and the output end of the second amplifier circuit 20 is coupled to the signal output end Vout. It is configured to amplify the RF input signal received by the signal input end Vin and output the amplified RF signal. It should be noted that the amplified RF signal could be an amplified signal with high linearity acquired by amplifying the RF input signal by the first amplifier circuit 10 when the low noise amplifier circuit works in the high linearity mode. Alternatively, the amplified RF signal could be an amplified signal with high gain acquired by amplifying the RF input signal by the first amplifier circuit 10 and the second amplifier circuit 20 when the low noise amplifier circuit works in the high gain mode.

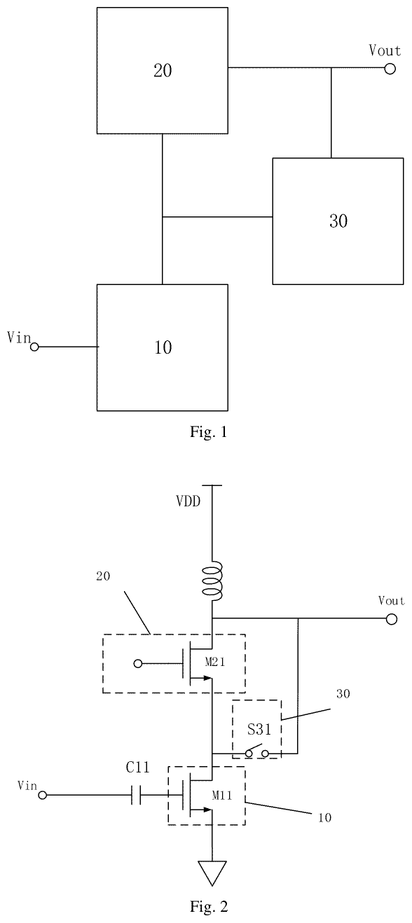

As an example, as shown in FIG. 2, the first switching circuit 30 may include a first switch S31. An end of the first switch S31 is connected to the output end of the first amplifier circuit 10, and the other end is connected to the signal output end Vout. In this example, when the low noise amplifier circuit works in the high gain mode, the first switch S31 is turned off, and the RF input signal cannot be directly output from the signal output end Vout through the first switch S31 after being amplified by the first amplifier circuit 10. In this way, the RF input signal amplified by the first amplifier circuit 10 is transmitted to the second amplifier circuit 20 for further amplification to ensure the high gain of the low noise amplifier circuit. After the RF input signal is amplified by the first amplifier circuit 10 and the second amplifier circuit 20 respectively, an amplified RF signal with high power can be obtained, thus realizing the high gain of the low noise amplifier circuit. When the low noise amplifier circuit works in the high linearity mode, the first switching circuit 30 is turned on. In this way, the RF input signal amplified by the first amplifier circuit 10 can be directly transmitted to the signal output end Vout for output via the first switching circuit 30, so that the low noise amplifier circuit has good linearity in the high linearity mode. The power of the amplified RF signal after the RF input signal is only amplified by the first amplifier circuit 10 is relatively small, thus realizing the high linearity of the low noise amplifier circuit. In this example, simply by controlling the on/off state of the first switch S31, the low noise amplifier circuit can have good linearity in the high linearity mode.

As another example, the first amplifier circuit 10 may include a first amplifier transistor M11, and the second amplifier circuit 20 may include a second amplifier transistor M21. Both the first amplifier transistor M11 and second amplifier transistor M21 may be BJT transistors (e.g., HBT transistors) or field effect transistors. For example, when both the first amplifier transistor M11 and the second amplifier transistor M21 are HBT transistors, both the first amplifier transistor M11 and the second amplifier transistor M21 may be NPN transistors or PNP transistors.

Further, the low noise amplifier circuit further includes a DC blocking capacitor C11 arranged between the signal input end Vin and the base (gate) of the first amplifier transistor M11. The DC blocking capacitor C11 is configured to filter DC signals from RF input signals. The base (gate) of the first amplifier transistor M11 is connected to the DC blocking capacitor C11, the collector (source) is connected to the emitters (drains) of the first switching circuit 30 and the second amplifier transistor M21, respectively, and the emitter of the first amplifier transistor M11 is connected to the ground terminal. The base (gate) of the second amplifier transistor M21 is connected to the power supply terminal VDD, the collector (source) is connected to the signal output end Vout, and the emitter is connected to the collector (source) of the first amplifier circuit 10.

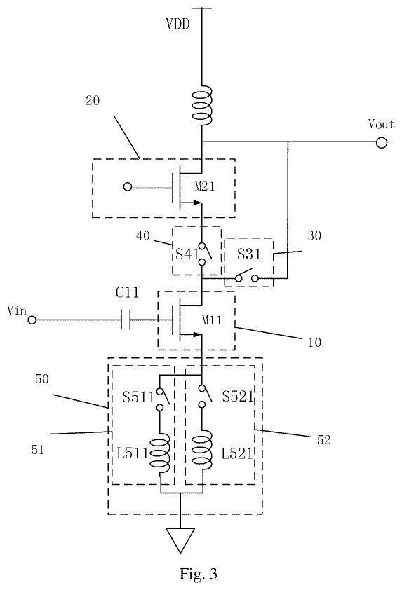

In a specific embodiment, as shown in FIG. 3, the low noise amplifier circuit further includes an induction regulating circuit 50, an end of the induction regulating circuit 50 is connected with the first amplifier circuit 10, and another end of the induction regulating circuit 50 is connected with the ground terminal.

In this embodiment, in order to further enable the low noise amplifier circuit to maintain good linearity in the high linearity mode, the low noise amplifier circuit also includes an induction regulating circuit 50, an end of the induction regulating circuit 50 is connected with the first amplifier circuit 10, and another end is connected with the ground terminal. Here, the induction regulating circuit 50 is a circuit with adjustable inductance value. By adjusting the inductance value of the induction regulating circuit 50, the low noise amplifier circuit can maintain better linearity in the high linearity mode.

In a specific embodiment, the low noise amplifier circuit includes a high gain mode and a high linearity mode, wherein in the high gain mode, the first switching circuit 30 is turned on, and the induction regulating circuit 50 presents a first inductance value; in the high linearity mode, the first switching circuit 30 is turned off, and the induction regulating circuit 50 presents a second inductance value, and the first inductance value is smaller than the second inductance value.

Specifically, the inductance value presented by the induction regulating circuit 50 in the high gain mode is smaller than that in the high linearity mode.

As an example, when the low noise amplifier circuit works in the high gain mode, in order to ensure the gain of the low noise amplifier circuit, the inductance value of the induction regulating circuit 50 is set to a small value. When the inductance value of the induction regulating circuit 50 is small, the feedback of the low noise amplifier circuit is weak, allowing the low noise amplifier circuit to maintain high gain in the high gain mode.

As an example, when the low noise amplifier circuit works in the high linearity mode, in order to ensure the linearity of the low noise amplifier circuit, the inductance value of the induction regulating circuit 50 is set to a large value. When the inductance value of the induction regulating circuit 50 is large, the feedback of the low noise amplifier circuit is strong, allowing the low noise amplifier circuit to maintain good linearity in the high linearity mode, thus further effectively improving the input third-order intercept point IIP3. In this embodiment, it is necessary to ensure that the inductance value presented by the induction regulating circuit 50 in the high gain mode is smaller than that in the high linearity mode, so that the low noise amplifier circuit can maintain good linearity in the high linearity mode.

In a specific embodiment, when the low noise amplifier circuit works in the high gain mode, the first switching circuit 30 is turned off, and the RF input signal is amplified for the first time by the first amplifier transistor M11 and then input to the second amplifier transistor M21 for amplification for the second time, so as to ensure the high gain of the low noise amplifier circuit.

In this embodiment, an end of the first switching circuit 30 is connected with the output end of the first amplifier circuit 10, and another end is connected with the signal output end Vout. It is configured that when the low noise amplifier circuit works in the high gain mode, the first switching circuit 30 is turned off, allowing the first amplifier circuit 10 and second amplifier circuit 20 to cooperate with each other to amplify the RF input signal, thus realizing the high gain of the low noise amplifier circuit. When the low noise amplifier circuit works in the high linearity mode, the first switching circuit 30 is turned on to connect the output end of the first amplifier circuit 10 with the signal output end Vout, allowing the RF input signal to be amplified through the first amplifier circuit 10 and then output from the signal output end Vout, so that the low noise amplifier circuit has good linearity in the high linearity mode.

In an embodiment, as shown in FIG. 3, the low noise amplifier circuit further includes a second switching circuit 40, an end of the second switching circuit 40 is connected with the output end of the first amplifier circuit 10, and another end of the second switching circuit 40 is connected with the input end of the second amplifier circuit 20; when the low noise amplifier circuit works in the high linearity mode, the second switching circuit 40 is turned off, and when the low noise amplifier circuit works in the high gain mode, the second switching circuit 40 is turned on.

As an example, the low noise amplifier circuit further includes a second switching circuit 40, the second switching circuit 40 may include a second switch S41, an end of the second switch S41 is connected with the output end of the first amplifier circuit 10 and another end is connected with the input end of the second amplifier circuit 20. In this example, when the low noise amplifier circuit works in the high linearity mode, the second switch S41 is off and the first switch S31 is on. The RF input signal amplified by the first amplifier circuit 10 is transmitted to the signal output end Vout through the first switching circuit 30 for output. When the low noise amplifier circuit works in the high linearity mode, the RF input signal amplified by the first amplifier circuit 10 would leak into the second amplifier circuit 20, which could affect the linearity of the low noise amplifier circuit. In the application, the second switch S41 is connected between the output end of the first amplifier circuit 10 and the input end of the second amplifier circuit 20 to avoid this situation. In this example, when the low noise amplifier circuit works in the high gain mode, the second switch S41 is on and the first switch S31 is off. After being amplified by the first amplifier circuit 10, the RF input signal is then transmitted to the second amplifier circuit 20 connected in series with the first amplifier circuit 10 for further amplification. At this point, the first switch S31 is in the off state, preventing the RF input signal, which has been amplified by the first amplifier circuit 10, from leaking directly to the signal output end Vout.

In this embodiment, when the low noise amplifier circuit works in the high linearity mode, the second switching circuit 40 is turned off and the first switching circuit 30 is turned on; when the low noise amplifier circuit works in the high gain mode, the first switching circuit 30 is turned off and the second switching circuit 40 is turned on. Based on the gain state of the low noise amplifier circuit, by controlling the on/off state of the first switch and the second switch, the low noise amplifier circuit can achieve optimal performance in the high linearity mode, and then the noise coefficient, linearity and other parameters can also be optimized in the high linearity mode.

In an embodiment, as shown in FIG. 3, the induction regulating circuit 50 includes a first regulating circuit 51 and a second regulating circuit 52 connected in parallel; the first regulating circuit 51 includes a first regulating switch S511 and a first regulating inductor L511 connected in series, and the second regulating circuit 52 includes a second regulating switch S521 and a second regulating inductor L521; when the low noise amplifier circuit works in the high linearity mode, the first regulating switch S511 is on and the second regulating switch S521 is off; when the low noise amplifier circuit works in the high gain mode, the second regulating switch S521 is on and the first regulating switch S511 is off; wherein the inductance value of the first regulating inductor L511 is greater than that of the second regulating inductor L521.

In this embodiment, the inductance value of the first regulating inductor L511 is greater than that of the second regulating inductor L521, when the low noise amplifier circuit works in the high linearity mode, the first regulating switch S511 is on and the second regulating switch S521 is off, the low noise amplifier circuit would select the first regulating inductor L511 with a large inductance value, which makes the feedback of the low noise amplifier circuit strong. Therefore, the low noise amplifier circuit can maintain good linearity in high linearity mode. When the low noise amplifier circuit works in the high gain mode, the second regulating switch S521 is on, and the first regulating switch S511 is off, the low noise amplifier circuit would select the second regulating inductor L521 with a smaller inductance value, which makes the feedback of the low noise amplifier circuit weak. Therefore, the low noise amplifier circuit can maintain high gain in high gain mode. In this embodiment, by controlling the on/off states of the first regulating switch and the second regulating switch, the low noise amplifier circuit can maintain good linearity in the high linearity mode.

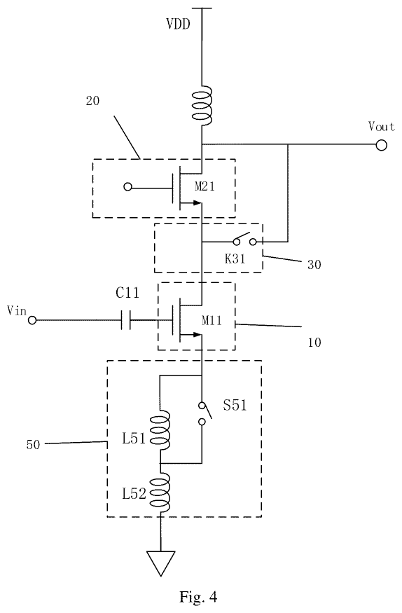

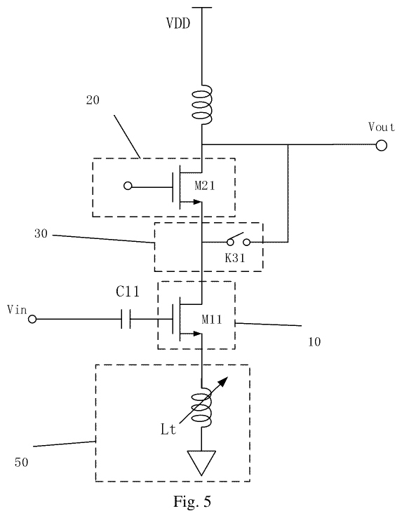

In an embodiment, as shown in FIG. 4, the induction regulating circuit 50 includes a plurality of regulating inductors and a gain switch S51; the plurality of regulating inductors are connected in series between the first amplifier circuit 10 and the ground terminal, the gain switch S51 is connected in parallel with any one of the regulating inductors, and when the low noise amplifier circuit works in the high linearity mode, the gain switch S51 is off; when the low noise amplifier circuit works in the high gain mode, the gain switch S51 is on.

As an example, the induction regulating circuit 50 includes M regulating inductors, M is greater than 1, M regulating inductors are connected in series between the first amplifier circuit 10 and the ground terminal, and the gain switch S51 is connected in parallel with any one of the M regulating inductors.

In this example, when the low noise amplifier circuit works in the high linearity mode, the gain switch S51 is off, and all the regulating inductors in the induction regulating circuit 50 participate in the gain adjustment of the low noise amplifier circuit. When the low noise amplifier circuit works in the high gain mode, the gain switch S51 is on, and the regulating inductor in the induction regulating circuit 50, which is in parallel with the gain switch S51, is short-circuited by the gain switch S51. And the rest of the regulating inductors in the induction regulating circuit 50 participate in the gain adjustment of the low noise amplifier circuit.

Referring to FIG. 4 below, the induction regulating circuit 50 includes two regulating inductors (a first regulating inductor L51 and a second regulating inductor L52) and a gain switch S51. The first end of the first regulating inductor L51 is connected with the first amplifier circuit 10, the second end is connected with the first end of the second regulating inductor L52; the second end of the second regulating inductor L52 is connected with the ground terminal; an end of the gain switch S51 is connected with the first amplifier circuit 10, and the other end is coupled to the connection path between the first regulating inductor L51 and the second regulating inductor L52. When the low noise amplifier circuit works in the high linearity mode, the gain switch S51 is on, and the first regulating inductor L511 and the second regulating inductor L521 corresponding to the high linearity mode are selected and connected. When the low noise amplifier circuit works in the high linearity mode, the gain switch S51 is off, and the second regulating inductor L521 corresponding to the high linearity mode is selected and connected.

In another specific embodiment, an end of the gain switch S51 is coupled to the connection path between the first regulating inductor L51 and the second regulating inductor L52, and the other end is connected to the ground terminal. When the low noise amplifier circuit works in the high linearity mode, the gain switch S51 is on, and the first regulating inductor L511 and the second regulating inductor L521 corresponding to the high linearity mode are selected and connected. When the low noise amplifier circuit works in the high linearity mode, the gain switch S51 is off, and the first regulating inductor L511 corresponding to the high linearity mode is selected and connected.

It should be noted that when the low noise amplifier circuit works in the high gain mode, the second regulating inductor L521 is connected, and the inductance value of the second regulating inductor L521 is smaller than the sum of the inductance values of the first regulating inductor L511 and the second regulating inductor L521, so that the feedback of the low noise amplifier circuit is weak. Therefore, the low noise amplifier circuit can maintain high gain in high gain mode. When the low noise amplifier circuit works in the high linearity mode, the first regulating inductor L511 and the second regulating inductor L521 are connected, so that the feedback of the low noise amplifier circuit is strong. Therefore, the low noise amplifier circuit can maintain good linearity in high linearity mode.

In this embodiment, the induction regulating circuit 50 includes a plurality of regulating inductors and a gain switch S51; the plurality of regulating inductors are connected in series between the first amplifier circuit 10 and the ground terminal, the gain switch S51 is connected in parallel with any one of the regulating inductors. The low noise amplifier circuit can enable the low noise amplifier circuit to maintain good linearity in the high linearity mode by the gain switch S51.

In an embodiment, as shown in FIG. 5, the induction regulating circuit 50 includes an adjustable inductor Lt; when the low noise amplifier circuit works in the high linearity mode, the inductance value of the adjustable inductor Lt is adjusted to the second inductance value; and when the low noise amplifier circuit works in the high gain mode, the inductance value of the adjustable inductor Lt is adjusted to the first inductance value. The first inductance value is smaller than the second inductance value.

As an example, when the low noise amplifier circuit works in the high linearity mode, in order to ensure the linearity of the low noise amplifier circuit, the inductance value of the adjustable inductor Lt is adjusted to the first inductance value. Because the first inductance value is smaller than the second inductance value, the low noise amplifier circuit has strong feedback, which enables the low noise amplifier circuit to maintain good linearity in high linearity mode, thus further effectively improving the input third-order intercept point IIP3.

As an example, when the low noise amplifier circuit works in the high gain mode, in order to ensure the gain of the low noise amplifier circuit, the inductance value of the adjustable inductor Lt is adjusted to the second inductance value. Because the second inductance value is larger than the first inductance value, the low noise amplifier circuit has weak feedback, which enables the low noise amplifier circuit to maintain a good gain in the high gain mode, thus further effectively improving the input third-order intercept point IIP3.

In this embodiment, it is necessary to ensure that the inductance value of the induction regulating circuit 50 in the high linearity mode is greater than that in the high gain mode, that is, the first inductance value is greater than the second inductance value, so that the low noise amplifier circuit can maintain good linearity when in the high linearity mode.

In an embodiment, as shown in FIG. 2, the first amplifier circuit 10 includes a first amplifier transistor M11, and the second amplifier circuit 20 includes at least one second amplifier transistor M21 connected in series.

In a specific embodiment, a first end of the first amplifier transistor M11 is coupled to the signal input end Vin, a second end of the first amplifier transistor M11 is connected to the induction regulating circuit 50, and a third end of the first amplifier transistor M11 is coupled to the input end of the second amplifier circuit 20.

In a specific embodiment, the second amplifier circuit 20 includes a second amplifier transistor M21, a first end of the second amplifier transistor M21 is connected with a first power supply terminal, a second end of the second amplifier transistor M21 is coupled to the third end of the first amplifier transistor M11, and a third end of the second amplifier transistor M21 is coupled to the signal output end Vout.

In a specific embodiment, the first amplifier transistor M11 is a first MOS transistor, a gate of the first MOS transistor is the first end of the first amplifier transistor M11, a drain of the first MOS transistor is the second end of the first amplifier transistor M11, and a source of the first MOS transistor is the third end of the first amplifier transistor M11.

In a specific embodiment, the second amplifier transistor M21 is a second MOS transistor, a gate of the second MOS transistor is the first end of the second amplifier transistor M21, a drain of the second MOS transistor is the second end of the second amplifier transistor M21, and a source of the second MOS transistor is the third end of the second amplifier transistor M21.

In a specific embodiment, when the low noise amplifier circuit works in the high gain mode, the first switch S31 is off, and the RF input signal cannot be directly output from the signal output end Vout via the first switch S31 after being amplified by the first amplifier circuit 10. Thus, the RF input signal amplified by the first amplifier circuit 10 is transmitted to the second amplifier circuit 20 for further amplification. In this example, the second amplifier circuit 20 includes at least one second amplifier transistor M21 connected in series, thus each series-connected second amplifier transistor M21 can further amplify the RF input signal, which has been amplified by the first amplifier circuit 10. After the RF input signal is amplified by the first amplifier circuit 10 and the second amplifier circuit 20 respectively, a high-power RF amplified signal can be obtained, thus realizing the high gain of the low noise amplifier circuit.

In this embodiment, the specific parameters of the first amplifier transistor M11 and the second amplifier transistor M21 can be determined according to the amplification multiple of the required RF input signal, so as to realize high gain of the low noise amplifier circuit.

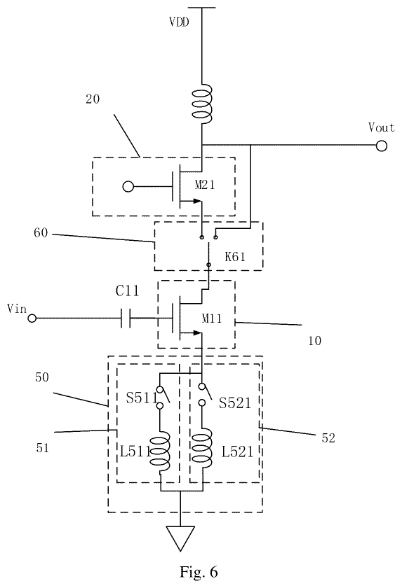

This embodiment provides a low noise amplifier circuit, as shown in FIG. 6, which includes a signal input end Vin, a signal output end Vout, a first amplifier circuit 10, a second amplifier circuit 20, a SPDT switching circuit 60 and an induction regulating circuit 50. A first end of the SPDT switching circuit 60 is connected with an output end of the first amplifier circuit 10, a second end of the SPDT switching circuit 60 is connected with an input end of the second amplifier circuit 20, and a third end of the SPDT switching circuit 60 is connected with the signal output end Vout. An end of the induction regulating circuit 50 is connected with the first amplifier circuit 10, and another end of the induction regulating circuit 50 is connected with a ground terminal. The low noise amplifier circuit includes a high gain mode and a high linearity mode, in the high gain mode, the first switching circuit 30 is turned on, and the induction regulating circuit 50 presents a first inductance value; in the high linearity mode, the first switching circuit 30 is turned off, and the induction regulating circuit 50 presents a second inductance value, and the first inductance value is smaller than the second inductance value.

As an example, the SPDT switching circuit 60 may include a single-pole double-throw switch K61, the first end of the single-pole double-throw switch K61 is connected with the output end of the first amplifier circuit 10, the second end of the single-pole double-throw switch K61 is connected with the input end of the second amplifier circuit 20, and the third end of the single-pole double-throw switch K61 is connected with the signal output end Vout. In this example, when the low noise amplifier circuit works in the high linearity mode, the single-pole double-throw switch K61 conducts the first end and the third end, so that the output end of the first amplifier circuit 10 and the signal output end Vout are conducted through the first end and the third end of the single-pole double-throw switch K61. In this state, the output end of the first amplifier circuit 10 is disconnected from the input end of the second amplifier circuit 20, and the RF input signal amplified by the first amplifier circuit 10 can be directly input via the first end of the single-pole double-throw switch K61, and then output from the third end to the signal output end Vout, thereby realizing that the low noise amplifier circuit has good linearity in the high linearity mode. In this example, when the low noise amplifier circuit works in the high gain mode, the single-pole double-throw switch K61 conducts the first end and the second end, so that the output end of the first amplifier circuit 10 and the input end of the second amplifier circuit 20 are conducted through the first end and the second end of the single-pole double-throw switch K61. In this state, the output end of the first amplifier circuit 10 and the signal output end Vout are disconnected, the RF input signal amplified by the first amplifier circuit 10 is input from the first end of the single-pole double-throw switch K61, and then output from the second end to the second amplifier circuit 20 for further amplification, thereby realizing that the low noise amplifier circuit has higher gain in the high gain mode.

In a specific embodiment, the low noise amplifier circuit further includes an induction regulating circuit 50, an end of the induction regulating circuit 50 is connected with the first amplifier circuit 10, and the other end is connected with the ground terminal.

In this embodiment, in order to further enable the low noise amplifier circuit to maintain good linearity in the high linearity mode, In the low noise amplifier circuit, an end of the induction regulating circuit 50 is connected to the first amplifier circuit 10, and the other end is connected to the ground terminal. Here, the induction regulating circuit 50 is a circuit with adjustable inductance value. By adjusting the inductance value of the induction regulating circuit 50, the low noise amplifier circuit can maintain better linearity in the high linearity mode.

In a specific embodiment, the low noise amplifier circuit includes a high gain mode and a high linearity mode. In the high gain mode, the single-pole double-throw switch K61 conducts the first end and the second end, and the induction regulating circuit 50 presents a first inductance value. In the high linearity mode, the single-pole double-throw switch K61 conducts the first end and the third end, and the induction regulating circuit 50 presents a second inductance value, and the first inductance value is smaller than the second inductance value.

Specifically, the inductance value presented by the induction regulating circuit 50 in the high gain mode is smaller than that in the high linearity mode.

As an example, when the low noise amplifier circuit works in the high gain mode, in order to ensure the gain of the low noise amplifier circuit, the inductance value of the induction regulating circuit 50 is set to a small value. When the inductance value of the induction regulating circuit 50 is small, the feedback of the low noise amplifier circuit is weak, allowing the low noise amplifier circuit to maintain high gain in the high gain mode.

As an example, when the low noise amplifier circuit works in the high linearity mode, in order to ensure the linearity of the low noise amplifier circuit, the inductance value of the induction regulating circuit 50 is set to a large value. When the inductance value of the induction regulating circuit 50 is large, the feedback of the low noise amplifier circuit is strong, allowing the low noise amplifier circuit to maintain good linearity in the high linearity mode, thus further effectively improving the input third-order intercept point IIP3. In this embodiment, it is necessary to ensure that the inductance value presented by the induction regulating circuit 50 in the high gain mode is smaller than that in the high linearity mode, so that the low noise amplifier circuit can maintain good linearity in the high linearity mode.

In this embodiment, when the low noise amplifier circuit works in the high gain mode, the single-pole double-throw switch K61 conducts the first end and the second end, the RF input signal is amplified for the first time by the first amplifier transistor M11, and then input to the second amplifier transistor M21 for amplification for the second time, thus ensuring the high gain of the low noise amplifier circuit.

In an embodiment, the SPDT switching circuit 60 includes a moving end, a first fixed end and a second fixed end; the moving end of the SPDT switching circuit 60 is connected with the output end of the first amplifier circuit 10, the first fixed end of the SPDT switching circuit 60 is connected with the input end of the second amplifier circuit 20, and the second fixed end of the SPDT switching circuit 60 is connected with the signal output end Vout.

In a specific embodiment, the first end of the single-pole double-throw switch K61 is a moving end, the second end of the single-pole double-throw switch K61 is a first fixed end, and the second end of the single-pole double-throw switch K61 is a second fixed end. In this embodiment, when the low noise amplifier circuit works in the high gain mode, the SPDT switching circuit 60 conducts the moving end and the first fixed end, the RF input signal is amplified for the first time by the first amplifier circuit 10, and then input to the second amplifier circuit 20 for amplification for the second time, thus ensuring the high gain of the low noise amplifier circuit.

When the low noise amplifier circuit works in the high linearity mode, the SPDT switching circuit 60 conducts the moving end and the second fixed end, so that the output end of the first amplifier circuit 10 and the signal output end Vout are connected through the moving end and the second fixed end of the SPDT switching circuit 60. In this state, the output end of the first amplifier circuit 10 is disconnected from the input end of the second amplifier circuit 20, and the RF input signal amplified by the first amplifier circuit 10 can be directly input via the moving end of the SPDT switching circuit 60, and output from the second fixed end to the signal output end Vout, thereby realizing that the low noise amplifier circuit has good linearity in the high linearity mode.

In a specific embodiment, as shown in FIG. 6, the first amplifier circuit 10 includes a first amplifier transistor M11, the first amplifier transistor M11 is a MOS transistor, and a gate of the first amplifier transistor M11 is coupled to the signal input end Vin, a drain of the first amplifier transistor M11 is connected with the induction regulating circuit 50, and a source of the first amplifier transistor M11 is connected with the first end of the SPDT switching circuit 60.

In a specific embodiment, as shown in FIG. 6, the second amplifier circuit 20 includes a second amplifier transistor M21, the second amplifier transistor M21 is a MOS transistor, a gate of the second amplifier transistor M21 is connected to a first power supply terminal, a drain of the second amplifier transistor M21 is connected to the second end of the SPDT switching circuit 60, and a source of the second amplifier transistor M21 is coupled to the signal output end Vout.

In a specific embodiment, when the low noise amplifier circuit works in the high gain mode, the SPDT switching circuit 60 conducts the moving end and the first fixed end, so that the RF input signal amplified by the first amplifier circuit 10 is transmitted to the second amplifier circuit 20 for further amplification. In this example, the second amplifier circuit 20 includes at least one second amplifier transistor M21 connected in series, thus each series-connected second amplifier transistor M21 can further amplify the RF input signal, which has been amplified by the first amplifier circuit 10. After the RF input signal is amplified by the first amplifier circuit 10 and the second amplifier circuit 20 respectively, a high-power RF amplified signal can be obtained, thus realizing the high gain of the low noise amplifier circuit.

In this embodiment, the specific parameters of the first amplifier transistor M11 and the second amplifier transistor M21 can be determined according to the amplification multiple of the required RF input signal, so as to realize high gain of the low noise amplifier circuit.

This embodiment provides an RF front-end module, including the low noise amplifier circuit described in the above embodiment, used for improving the gain and linearity.

The above embodiments are only used to illustrate the technical solutions of the present application, but not to limit it. Although the present application has been described in detail with reference to the foregoing embodiments, those skilled in the art would understand that it is possible to modify the technical solutions described in the foregoing embodiments, or to replace some technical features with equivalents. However, these modifications or substitutions do not make the essence of the corresponding technical solutions deviate from the spirit and scope of the technical solutions of various embodiments of the present application, and shall be included in the protection scope of the present application. Further, unless otherwise required by context, singular terms shall include pluralities and plural terms shall include the singular.

What is claimed is:

1. A low noise amplifier circuit, comprising a signal input end, a signal output end, a first amplifier circuit, a second amplifier circuit, a first switching circuit, an induction regulating circuit, a high gain mode and a high linearity mode; wherein
an input end of the first amplifier circuit is coupled to the signal input end, an output end of the first amplifier circuit is coupled to an input end of the second amplifier circuit, and an output end of the second amplifier circuit is coupled to the signal output end;
an end of the first switching circuit is connected with the output end of the first amplifier circuit, and another end of the first switching circuit is connected with the signal output end;
an end of the induction regulating circuit is connected with the first amplifier circuit, and another end of the induction regulating circuit is connected with a ground terminal; and
in the high gain mode, the first switching circuit is turned on, and the induction regulating circuit presents a first inductance value; in the high linearity mode, the first switching circuit is turned off, and the induction regulating circuit presents a second inductance value, and the first inductance value is smaller than the second inductance value.

2. The low noise amplifier circuit of claim 1, further comprising a second switching circuit, wherein an end of the second switching circuit is connected with the output end of the first amplifier circuit, and another end of the second switching circuit is connected with the input end of the second amplifier circuit; when the low noise amplifier circuit works in the high linearity mode, the second switching circuit is turned off, and when the low noise amplifier circuit works in the high gain mode, the second switching circuit is turned on.

3. The low noise amplifier circuit of claim 1, wherein the induction regulating circuit comprises a first regulating circuit and a second regulating circuit connected in parallel; the first regulating circuit comprises a first regulating switch and a first regulating inductor connected in series, and the second regulating circuit comprises a second regulating switch and a second regulating inductor; when the low noise amplifier circuit works in the high linearity mode, the first regulating switch is on and the second regulating switch is off; when the low noise amplifier circuit works in the high gain mode, the second regulating switch is on and the first regulating switch is off; wherein the inductance value of the first regulating inductor is greater than that of the second regulating inductor.

4. The low noise amplifier circuit of claim 1, wherein the induction regulating circuit comprises a plurality of regulating inductors and a gain switch; the plurality of regulating inductors are connected in series between the first amplifier circuit and the ground terminal, the gain switch is connected in parallel with any one of the regulating inductors, and when the low noise amplifier circuit works in the high linearity mode, the gain switch is off; when the low noise amplifier circuit works in the high gain mode, the gain switch is on.

5. The low noise amplifier circuit of claim 1, wherein the induction regulating circuit comprises an adjustable inductor; when the low noise amplifier circuit works in the high linearity mode, the inductance value of the adjustable inductor is adjusted to the second inductance value, and when the low noise amplifier circuit works in the high gain mode, the inductance value of the adjustable inductor is adjusted to the first inductance value.

6. The low noise amplifier circuit of claim 1, wherein the first amplifier circuit comprises a first amplifier transistor, a first end of the first amplifier transistor is coupled to the signal input end, a second end of the first amplifier transistor is connected to the induction regulating circuit, and a third end of the first amplifier transistor is coupled to the input end of the second amplifier circuit.

7. The low noise amplifier circuit of claim 6, wherein the second amplifier circuit comprises a second amplifier transistor, a first end of the second amplifier transistor is connected with a first power supply terminal, a second end of the second amplifier transistor is coupled to the third end of the first amplifier transistor, and a third end of the second amplifier transistor is coupled to the signal output end.

8. The low noise amplifier circuit of claim 7, wherein the first amplifier transistor is a first Metal-Oxide-Semiconductor (MOS) transistor, a gate of the first MOS transistor is the first end of the first amplifier transistor, a drain of the first MOS transistor is the second end of the first amplifier transistor, and a source of the first MOS transistor is the third end of the first amplifier transistor; the second amplifier transistor is a second MOS transistor, a gate of the second MOS transistor is the first end of the second amplifier transistor, a drain of the second MOS transistor is the second end of the second amplifier transistor, and a source of the second MOS transistor is the third end of the second amplifier transistor.

9. A low noise amplifier circuit, comprising a signal input end, a signal output end, a first amplifier circuit, a second amplifier circuit, a Single-Pole Double-Throw (SPDT) switching circuit, an induction regulating circuit, a high gain mode and a high linearity mode; wherein
a first end of the SPDT switching circuit is connected with an output end of the first amplifier circuit, a second end of the SPDT switching circuit is connected with an input end of the second amplifier circuit, and a third end of the SPDT switching circuit is connected with the signal output end;
an end of the induction regulating circuit is connected with the first amplifier circuit, and another end of the induction regulating circuit is connected with a ground terminal; and
in the high gain mode, the SPDT switching circuit conducts the first end and the second end, and the induction regulating circuit presents a first inductance value; in the high linearity mode, the SPDT switching circuit conducts the first end and the third end, and the induction regulating circuit presents a second inductance value, and the first inductance value is smaller than the second inductance value.

10. The low noise amplifier circuit of claim 9, wherein the SPDT switching circuit comprises a moving end, a first fixed end and a second fixed end; the moving end of the SPDT switching circuit is connected with the output end of the first amplifier circuit, the first fixed end of the SPDT switching circuit is connected with the input end of the second amplifier circuit, and the second fixed end of the SPDT switching circuit is connected with the signal output end.

11. The low noise amplifier circuit of claim 9, wherein the first amplifier circuit comprises a first amplifier transistor, the first amplifier transistor is a MOS transistor, and a gate of the first amplifier transistor is coupled to the signal input end, a drain of the first amplifier transistor is connected with the induction regulating circuit, and a source of the first amplifier transistor is connected with the first end of the SPDT switching circuit.

12. The low noise amplifier circuit of claim 9, wherein the second amplifier circuit comprises a second amplifier transistor, the second amplifier transistor is a MOS transistor, a gate of the second amplifier transistor is connected to a first power supply terminal, a drain of the second amplifier transistor is connected to the second end of the SPDT switching circuit, and a source of the second amplifier transistor is coupled to the signal output end.

13. An RF front-end module, comprising the low noise amplifier circuit of claim 1.
